(19) United States
(12) Patent Application Publication
(10) Pub. No.: US 2024/0222251 A1
(43) Pub. Date: Jul. 4, 2024

(54) SEMICONDUCTOR PACKAGE AND METHOD OF FABRICATING THE SAME

(71) Applicant: Samsung Electronics Co., Ltd., Suwon-si (KR)

(72) Inventors: JIYOUNG LEE, Suwon-si (KR); JUNHYEONG PARK, Suwon-si (KR); JIHYE SHIM, Suwon-si (KR)

(21) Appl. No.: 18/236,664

(22) Filed: Aug. 22, 2023

(30) Foreign Application Priority Data
Jan. 3, 2023 (KR) 10-2023-0000835

(51) Int. Cl. H01L 23/498; H01L 21/48; H01L 23/00; H01L 25/065; H01L 25/10; H01L 25/18

(52) U.S. Cl. CPC H01L 23/49838; H01L 21/4857; H01L 23/49822; H01L 24/13; H01L 24/16; H01L 24/17; H01L 25/0657; H01L 25/105; H01L 25/18; H01L 24/05; H01L 24/06; H01L 2224/0557; H01L 2224/06181; H01L 2224/13082; H01L 2224/16145; H01L 2224/16227; H01L 2224/1703; H01L 2225/06513; H01L 2225/06517; H01L 2225/06541; H01L 2225/1035; H01L 2225/1041

(57) ABSTRACT

Disclosed are semiconductor packages and their fabrication methods. The semiconductor package comprises a first structure that includes a conductive pattern, a second structure spaced apart from the first structure, a pillar structure between the first structure and the second structure and electrically connecting the first structure to the second structure, and a semiconductor chip between the first structure and the second structure. The pillar structure includes an inner pillar on the conductive pattern and an outer pillar that surrounds the inner pillar. The outer pillar is in contact with a sidewall and a top surface of the inner pillar.

### CROSS-REFERENCE TO RELATED APPLICATION

This U.S. nonprovisional application claims priority under 35 U.S.C § 119 to Korean Patent Application No. 10-2023-0000835 filed on Jan. 3, 2023 in the Korean Intellectual Property Office, the disclosure of which is hereby incorporated by reference in its entirety.

### BACKGROUND

The present inventive concepts relate to a semiconductor package and a method of fabricating the same, and more particularly, to a semiconductor package including a connection structure and a method of fabricating the same.

A semiconductor package is provided to implement an integrated circuit chip to qualify for use in electronic products. Typically, a semiconductor package is configured such that a semiconductor chip is mounted on a printed circuit board and bonding wires or bumps are used to electrically connect the semiconductor chip to the printed circuit board. With the development of electronics industry, many studies have been conducted to improve reliability of semiconductor packages.

### SUMMARY

Some embodiments of the present inventive concepts provide a semiconductor package with improved electrical properties and increased reliability and a method of fabricating the same.

According to some embodiments of the present inventive concepts, a semiconductor package may comprise: a first structure that includes a conductive pattern; a second structure spaced apart from the first structure; a pillar structure between the first structure and the second structure, the pillar structure electrically connecting the first structure to the second structure; and a semiconductor chip between the first structure and the second structure. The pillar structure may include an inner pillar on the conductive pattern and an outer pillar that surrounds the inner pillar. The outer pillar may be in contact with a sidewall and a top surface of the inner pillar.

According to some embodiments of the present inventive concepts, a semiconductor package may comprise: a first structure that includes a conductive pattern; a second structure spaced apart in a first direction from the first structure; a pillar structure between the first structure and the second structure, the pillar structure electrically connecting the first structure to the second structure; and a semiconductor chip between the first structure and the second structure, the semiconductor chip being spaced apart from the pillar structure in a second direction that intersects the first direction. The pillar structure may include an inner pillar on the conductive pattern and an outer pillar that surrounds the inner pillar. A width in the second direction of the inner pillar may be less than a length in the first direction of the inner pillar.

According to some embodiments of the present inventive concepts, a semiconductor package may comprise: a first structure that includes a conductive pattern; a second structure spaced apart in a first direction from the first structure; a pillar structure between the first structure and the second structure, the pillar structure electrically connecting the first structure to the second structure; a first semiconductor chip mounted on the first structure and spaced apart from the pillar structure in a second direction that intersects the first direction; a second semiconductor chip mounted on the second structure; and a molding layer between the first structure and the second structure, the molding layer surrounding the first semiconductor chip and the pillar structure. The pillar structure may include an inner pillar on the conductive pattern and an outer pillar that surrounds the inner pillar. The inner pillar may include a sidewall parallel to the first direction and a top surface parallel to the second direction. The outer pillar may be in contact with the sidewall of the inner pillar and the top surface of the inner pillar.

According to some embodiments of the present inventive concepts, a method of fabricating a semiconductor package may comprise: forming a first structure that includes a conductive pattern; forming a first photoresist layer on the first structure; forming in the first photoresist layer a first opening to expose the conductive pattern; filling an inner pillar in the first opening; forming a second photoresist layer to cover the inner pillar; forming in the second photoresist layer a second opening to expose a sidewall and a top surface of the inner pillar; and forming an outer pillar in the second opening.

### BRIEF DESCRIPTION OF DRAWINGS

FIG. 1A illustrates a plan view showing a semiconductor package according to some embodiments.

FIG. 1B illustrates a cross-sectional view showing a semiconductor package of FIG. 1A.

FIG. 1C illustrates an enlarged view showing section A of FIG. 1B.

FIGS. 2A, 2B, 2C, 2D, 2E, 2F, 2G, 2H, and 2I illustrate cross-sectional views showing a method of fabricating a semiconductor package according to FIGS. 1A, 1B, and 1C.

FIG. 3 illustrates an enlarged cross-sectional view showing a semiconductor package according to some embodiments.

FIGS. 4A and 4B illustrate enlarged cross-sectional views showing a method of fabricating a semiconductor package according to FIG. 3.

FIG. 5 illustrates an enlarged cross-sectional view showing a semiconductor package according to some embodiments.

FIG. 6 illustrates a cross-sectional view showing a semiconductor package according to some embodiments.

FIG. 7 illustrates a cross-sectional view showing a semiconductor package according to some embodiments.

FIG. 8 illustrates a cross-sectional view showing a semiconductor package according to some embodiments.

FIG. 9 illustrates a cross-sectional view showing a semiconductor package according to some embodiments.

FIG. 10 illustrates a cross-sectional view showing a conductive structure according to some embodiments.

### DETAILED DESCRIPTION OF EMBODIMENTS

The following will describe in detail a semiconductor package and its fabrication method according to some embodiments of the present inventive concepts in conjunction with the accompanying drawings.

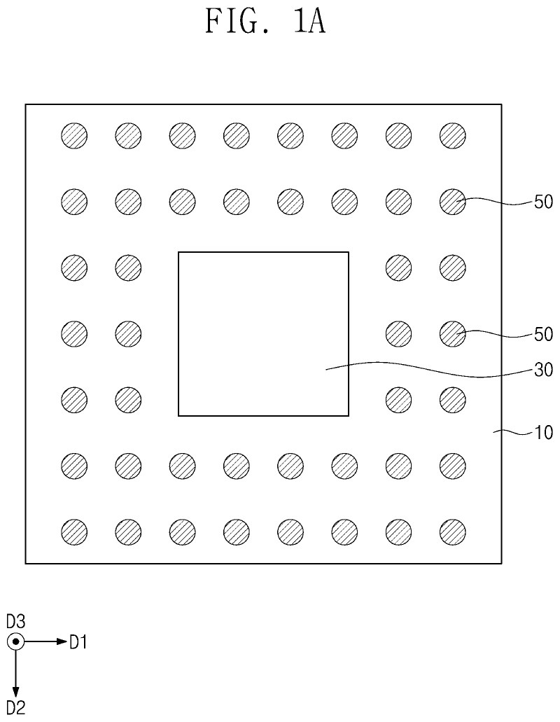

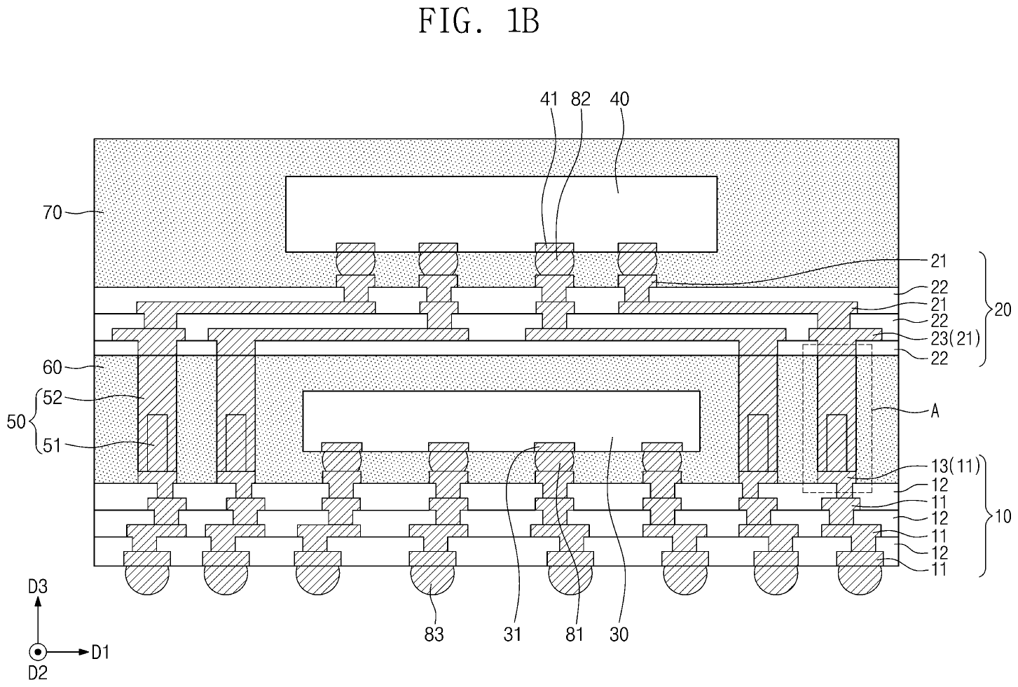

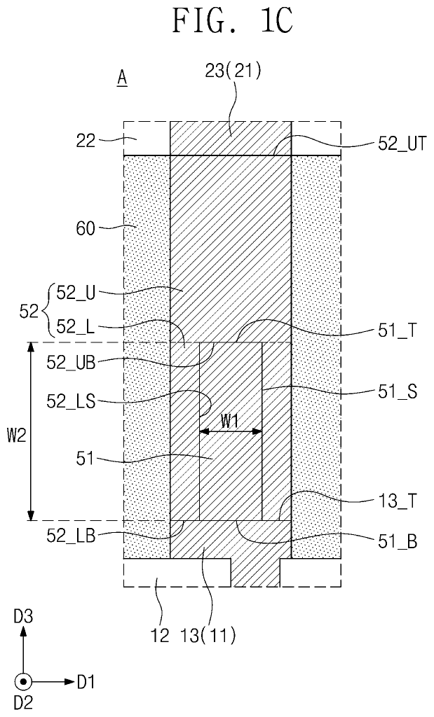

FIG. 1A illustrates a plan view showing a semiconductor package according to some embodiments. FIG. 1B illustrates a cross-sectional view showing a semiconductor package of FIG. 1A. FIG. 1C illustrates an enlarged view showing section A of FIG. 1B.

Referring to FIGS. 1A and 1B, a semiconductor package may include a first structure 10, a second structure 20, a first semiconductor chip 30, a second semiconductor chip 40, pillar structures 50, a first molding layer 60, a second molding layer 70, first bumps 81, second bumps 82, and third bumps 83.

The first structure 10 may include first conductive patterns 11 and first dielectric layers 12. The first dielectric layers 12 may have a plate shape that extends along a plane extending in a first direction D1 and a second direction D2. The first direction D1 and the second direction D2 may intersect each other. For example, the first direction D1 and the second direction D2 may be horizontal directions that are orthogonal to each other.

The first dielectric layers 12 may be sequentially stacked along a third direction D3. The third direction D3 may intersect the first direction D1 and the second direction D2. For example, the third direction D3 may be a vertical direction perpendicular to the first direction D1 and the second direction D2.

The first dielectric layers 12 may include or be formed of an organic material, such as a photo-imageable dielectric (PID) material. The photo-imageable dielectric material may include or be formed of, for example, at least one selected from photosensitive polyimide, polybenzoxazole, phenolic polymers, and benzocyclobutene polymers.

The first conductive pattern 11 may be surrounded by the first dielectric layers 12. In some embodiments, the first conductive pattern 11 may include a via part for vertical connection and a line part for horizontal connection. For example, the via part may extend in a vertical direction and the line part may extend in a horizontal direction. The via part of the first conductive pattern 11 may be located at a lower level than the line part of the first conductive pattern 11. A width of the via part of the first conductive pattern 11 in a horizontal direction may be less than a width of the line part of the first conductive pattern 11 in the horizontal direction. The first conductive patterns 11 located at an uppermost level may be defined as uppermost conductive patterns 13. The first conductive pattern 11 may include or be formed of a conductive material. For example, the first conductive pattern 11 may include or be formed of copper.

The first structure 10 may be a redistribution substrate including redistribution patterns. The first conductive pattern 11 of the first structure 10 may be a redistribution pattern. In some embodiments, the first structure 10 may be a printed circuit board or a semiconductor chip.

The second structure 20 may include second conductive patterns 21 and second dielectric layers 22. The second dielectric layers 22 may be sequentially stacked along the third direction D3. The second dielectric layers 22 may include or be formed of an organic material, such as a photo-imageable dielectric (PID) material.

The second conductive pattern 21 may be surrounded by the second dielectric layers 22. In some embodiments, the second conductive pattern 21 may include a via part for vertical connection and a line part for horizontal connection. For example, the via part may extend in a vertical direction and the line part may extend in a horizontal direction. The via part of the second conductive pattern 21 may be located at a lower level than the line part of the second conductive pattern 21. For example, each layer of the second conductive pattern 21 including a corresponding layer of line part and a corresponding layer of via part may be integrally formed by a pattern forming process and the via part of the integrally formed second conductive pattern 21 may be located at a lower level than the line part of the integrally formed second conductive pattern 21. The second conductive patterns 21 located at a lowermost level may be defined as lowermost conductive patterns 23. The second conductive pattern 21 may include or be formed of a conductive material. For example, the second conductive pattern 21 may include or be formed of copper.

The second structure 20 may be a redistribution substrate including redistribution patterns. The second conductive pattern 21 of the second structure 20 may be a redistribution pattern. In some embodiments, the second structure 20 may be a printed circuit board or a semiconductor chip.

Each of the first and second semiconductor chips 30 and 40 may include a semiconductor substrate. For example, the semiconductor substrate may include silicon, germanium, silicon-germanium, gallium-phosphorus, or gallium-arsenic. In some embodiments, each of the first and second semiconductor chips 30 and 40 may include a silicon-on-insulator (SOI) substrate or a germanium-on-insulator (GOI) substrate. In some embodiments, the first semiconductor chip 30 may be a logic chip, and the second semiconductor chip 40 may be a memory chip.

The first semiconductor chip 30 may include first pads 31. The first pad 31 may be electrically connected through the first bump 81 to the uppermost conductive pattern 13. The first pad 31 may include or be formed of a conductive material.

As used herein, components described as being “electrically connected” are configured such that an electrical signal can be transferred from one component to the other (although such electrical signal may be attenuated in strength as it transferred and may be selectively transferred).

The second semiconductor chip 40 may include second pads 41. The second pad 41 may be electrically connected through the second bump 82 to the second conductive pattern 21 of the second structure 20. The second pad 41 may include or be formed of a conductive material.

Spatially relative terms, such as “top,” “bottom,” “beneath,” “below,” “lower,” “above,” “upper,” “uppermost” and the like, may be used herein for ease of description to describe positional relationships. It will be understood that the spatially relative terms encompass different orientations of the device in addition to the orientation depicted in the figures.

The first semiconductor chip 30 may be disposed between the first structure 10 and the second structure 20. The second structure 20 may be disposed between the first semiconductor chip 30 and the second semiconductor chip 40. The first structure 10 and the second structure 20 may be spaced apart from each other in the third direction D3. The first structure 10, the first semiconductor chip 30, the second structure 20, and the second semiconductor chip 40 may be sequentially arranged along the third direction D3.

The pillar structures 50 may be disposed between the first structure 10 and the second structure 20. The pillar structures 50 may electrically connect the first structure 10 and the second structure 20 to each other. The pillar structures 50 may surround the first semiconductor chip 30. The pillar structures 50 may be disposed around the first semiconductor chip 30. Each pillar structure 50 may extend, e.g., lengthwise, in the third direction D3. The pillar structure 50 may have a length/height of equal to or greater than about 10 μm in the third direction D3. The pillar structure 50 may have an aspect ratio greater than 1. The pillar structure 50 may penetrate the first molding layer 60. The first semiconductor chip 30 and the pillar structures 50 may be located at the same level. For example, the first semiconductor chip 30 and the pillar structures 50 may overlap in a horizontal direction. The pillar structures 50 may be spaced apart from the first semiconductor chip 30 in the first direction D1 and/or the second direction D2. The first semiconductor chip 30 may be located at a lower level than a top surface of the pillar structure 50. A top surface of the first semiconductor chip 30 may be located at a lower level than the top surface of the pillar structure 50. For example, a top portion of each pillar structure 50 may not overlap the first semiconductor chip 30 in horizontal directions, e.g., in the first direction D1 and/or in the second direction D2. The first semiconductor chip 30 may be located at a higher level than a bottom surface of the pillar structure 50. A bottom surface of the first semiconductor chip 30 may be located at a higher level than a bottom surface of the pillar structure 50. For example, a bottom portion of each pillar structure 50 may not overlap the first semiconductor chip 30 in horizontal directions, e.g., in the first direction D1 and/or in the second direction D2.

The bottom surface of the pillar structure 50 may be in contact with the uppermost conductive pattern 13 of the first structure 10. The top surface of the pillar structure 50 may be in contact with the lowermost conductive pattern 23 of the second structure 20.

The first molding layer 60 may be disposed between the first structure 10 and the second structure 20. For example, a bottom surface of the first molding layer 60 contacts a top surface of the first structure 10 and a top surface of the first molding layer 60 contacts a bottom surface of the second structure 20. The first molding layer 60 may surround the first semiconductor chip 30 and the pillar structures 50. For example, the first molding layer 60 contacts side surfaces of the first semiconductor chip 30 and the pillar structures 50. The first molding layer 60 may also contact top and bottom surfaces of the first semiconductor chip 30. The first molding layer 60 may include or be formed of a polymeric material.

The second molding layer 70 may be disposed on the second structure 20. The second molding layer 70 may surround the second semiconductor chip 40. For example, the second molding layer 70 may contact side surfaces and top and bottom surfaces of the second semiconductor chip 40. The second molding layer 70 may include or be formed of a polymeric material.

The first bumps 81 may electrically connect the first semiconductor chip 30 to the first structure 10. The first bump 81 may be in contact with the first pad 31 of the first semiconductor chip 30 and the uppermost conductive pattern 13 of the first structure 10. The first bump 81 may include or be formed of a conductive material.

The second bumps 82 may electrically connect the second semiconductor chip 40 to the second structure 20. The second bump 82 may be in contact with the second pad 41 of the second semiconductor chip 40 and the second conductive pattern 21 of the second structure 20. The second bump 82 may be in contact with one at an uppermost level of the second conductive patterns 21. The second bump 82 may include or be formed of a conductive material.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The third bumps 83 may be connected to (e.g., contact) a lower portion (e.g., a bottom surface) of the first structure 10. The first bump 81 and the third bump 83 may be electrically connected through the first conductive patterns 11. The pillar structure 50 and the third bump 83 may be electrically connected through the first conductive patterns 11. The third bump 83 may be in contact with one at a lowermost level of the first conductive patterns 11. The third bump 83 may include or be formed of a conductive material.

Referring to FIG. 1C, the pillar structure 50 may include an inner pillar 51 and an outer pillar 52 that surrounds the inner pillar 51. The inner pillar 51 may have a circular pillar shape (e.g., a cylindrical shape). The inner pillar 51 may extend in the third direction D3, e.g., lengthwise. The inner pillar 51 may have an aspect ratio greater than 1. The inner pillar 51 may have a bottom surface 51_B in contact with a top surface 13_T of the uppermost conductive pattern 13. The inner pillar 51 may have a sidewall 51_S and a top surface 51_T that are in contact with the outer pillar 52. The top surface 51_T and the bottom surface 51_B of the inner pillar 51 may be parallel to the first direction D1. The top surface 51_T and the bottom surface 51_B of the inner pillar 51 may also be parallel to the second direction D2. The sidewall 51_S of the inner pillar 51 may be parallel to the third direction D3.

A width W1 in the first direction D1 of the inner pillar 51 may be less than a height (length) W2 in the third direction D3 of the inner pillar 51. For example, a maximum width in the first direction D1 of the inner pillar 51 may be less than a maximum height/length in the third direction D3 of the inner pillar 51. The width W1 in the first direction D1 of the inner pillar 51 may be less than a distance between the top surface 51_T and the bottom surface 51_B of the inner pillar 51. For example, the maximum width in the first direction D1 of the inner pillar 51 may be less than a minimum distance between the top surface 51_T and the bottom surface 51_B of the inner pillar 51. A width in the first direction D1 of the top surface 51_T of the inner pillar 51 may be less than a height/length in the third direction D3 of the sidewall 51_S of the inner pillar 51. For example, a maximum width in the first direction D1 of the top surface 51_T of the inner pillar 51 may be less than a maximum height/length in the third direction D3 of the sidewall 51_S of the inner pillar 51. The width W1 in the first direction D1 of the inner pillar 51 may be less than a width in the first direction D1 of the outer pillar 52. A width of the inner pillar 51 in the second direction D2 may be the same or substantially the same as the width W1 of the inner pillar 51 in the first direction D1.

Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

The outer pillar 52 may include a lower portion 52_L located at a lower level than the top surface 51_T of the inner pillar 51 and an upper portion 52_U located at a higher level than the top surface 51_T of the inner pillar 51. The lower portion 52_L of the outer pillar 52 may be located at the same level as that of the inner pillar 51. The lower portion 52_L of the outer pillar 52 may surround the inner pillar 51. The lower portion 52_L of the outer pillar 52 may have a cylindrical shape having an empty space therein. For example, the empty space of the lower portion 52_L of the outer pillar 52 may be filled with the inner pillar 51 thereby forming a solid pillar structure 50 without an empty portion therein. The lower portion 52_L of the outer pillar 52 may have a bottom surface 52_LB in contact with the top surface 13_T of the uppermost conductive pattern 13. The lower portion 52_L of the outer pillar 52 may have an inner sidewall 52_LS in contact with the sidewall 51_S of the inner pillar 51.

The upper portion of the outer pillar 52 may be located at a higher level than the inner pillar 51. For example, the bottom end of the upper portion of the outer pillar 52 may be at the same level as the top surface of the inner pillar 51. The upper portion 52_U of the outer pillar 52 may have a circular pillar shape, e.g., a cylindrical shape filled with solid (e.g., a solid cylinder). The upper portion 52_U of the outer pillar 52 may have a bottom surface 52_UB in contact with the top surface 51_T of the inner pillar 51. The upper portion 52_U of the outer pillar 52 may have a top surface 52_UT in contact with the lowermost conductive pattern 23 of the second structure 20. The bottom surface 52_UB of the upper portion 52_U of the outer pillar 52 may be parallel to the first direction D1 and the second direction D2, and the inner sidewall 52_LS of the lower portion 52_L of the outer pillar 52 may be (e.g., extend) parallel to the third direction D3. A width in the first direction D1 of the bottom surface 52_UB of the upper portion 52_U included in the outer pillar 52 may be less than a height/distance in the third direction D3 of the inner sidewall 52_LS of the lower portion 52_L included in the outer pillar 52.

The height (length) W2 in the third direction D3 of the inner pillar 51 may be equal to or less than about 0.5 times a height/length in the third direction D3 of the outer pillar 52. For example, the maximum height/length in the third direction D3 of the inner pillar 51 may be equal to or less than about 0.5 times a maximum height/length in the third direction D3 of the outer pillar 52. The distance between the top surface 51_T and the bottom surface 51_B of the inner pillar 51 may be equal to or less than about 0.5 times a distance between the top surface 52_UT of the upper portion 52_U and the bottom surface 52_LB of the lower portion 52_L of the outer pillar 52. A width of the inner pillar in a horizontal direction (e.g., the first direction D1 and/or the second direction D2) may be equal to or less than about 0.5 times a width of the outer pillar in the horizontal direction.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The uppermost conductive pattern 13, the inner pillar 51, and the outer pillar 52 may include or be formed of the same conductive material. For example, the uppermost conductive pattern 13, the inner pillar 51, and the outer pillar 52 may include or be formed of copper. In some embodiments, grains of the inner pillar 51 may have an average size less than that of grains of the outer pillar 52. In some embodiments, a density of grain boundaries in the inner pillar 51 and a density of grain boundaries in the outer pillar 52 may be less than a density of grain boundaries at an interface between the inner pillar 51 and the outer pillar 52. For example, grains sizes (e.g., an average grain size) of the material forming the inner pillar 51 and grains sizes (e.g., an average grain size) of the material forming the outer pillar 52 may be greater than grains sizes (e.g., an average grain size) of the materials at the interface/boundary between the inner pillar 51 and the outer pillar 52. The interface between the inner pillar 51 and the outer pillar 52 may be defined by the sidewall 51_S and the top surface 51_T of the inner pillar 51, the bottom surface 52_UB of the upper portion 52_U of the outer pillar 52, and the inner sidewall 52_LS of the lower portion 52_L of the outer pillar 52. In some embodiments, the density of grain boundaries in the inner pillar 51 may be greater than the density of grain boundaries in the outer pillar 52. For example, the densities of the grain boundaries and grain sizes in the inner pillar 51 and the outer pillar 52 in contrast to those at the interface may be densities of the grain boundaries and grain sizes of materials in respective inner/center portions (e.g., in bulk areas) of the inner pillar 51 and the outer pillar 52.

In a semiconductor package according to some embodiments, as the pillar structure 50 includes the inner pillar 51 and the outer pillar 52, the pillar structure 50 may have a uniform horizontal width and a uniform vertical width (height). Therefore the pillar structure 50 of the embodiments is helpful for the pillar structure 50 to electrically connect the first structure 10 and the second structure 20 to each other.

In a semiconductor package according to some embodiments, as the pillar structure 50 includes the inner pillar 51 and the outer pillar 52, the pillar structure 50 may have a flat top surface, and dimple failure may be avoided. For example, the pillar structure 50 of the embodiments is helpful for the pillar structure 50 to have a flat top surface.

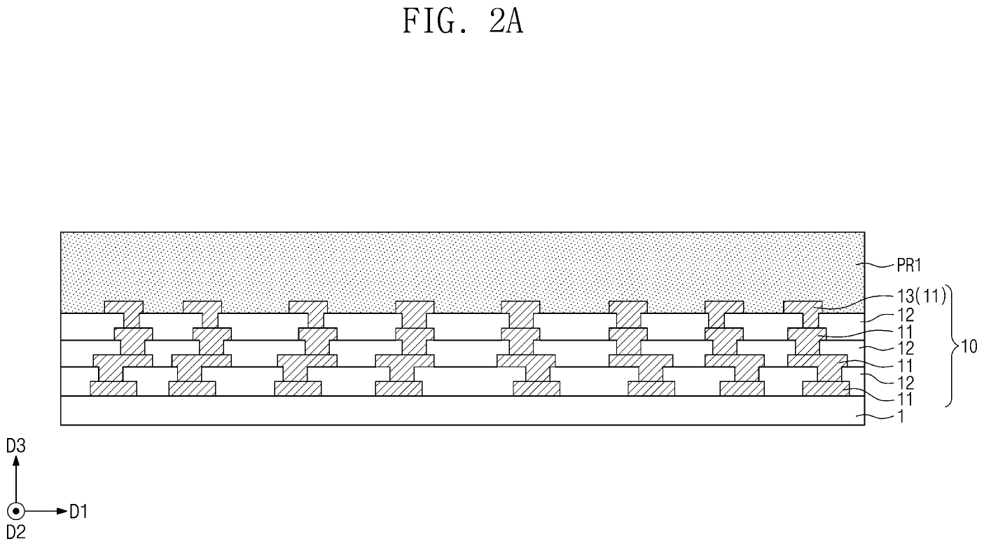

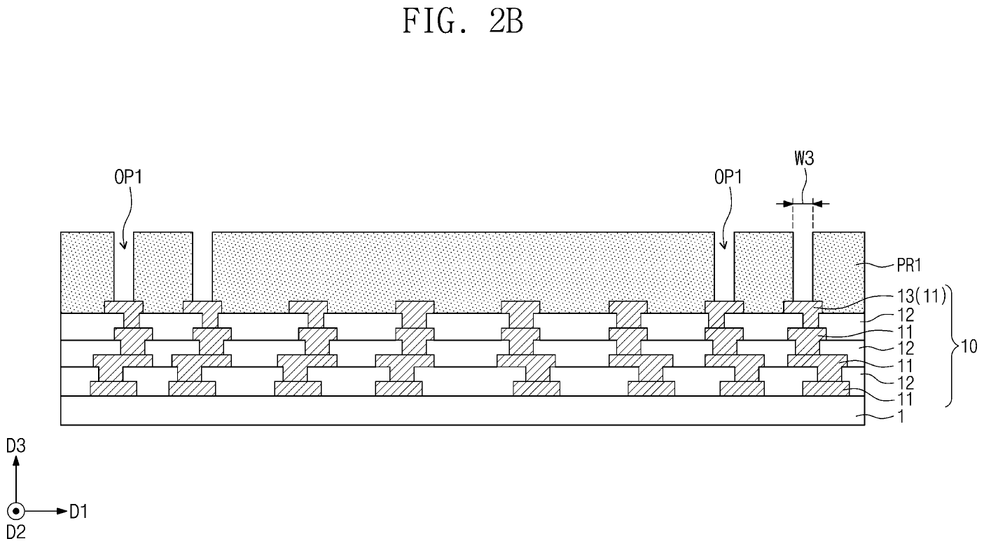

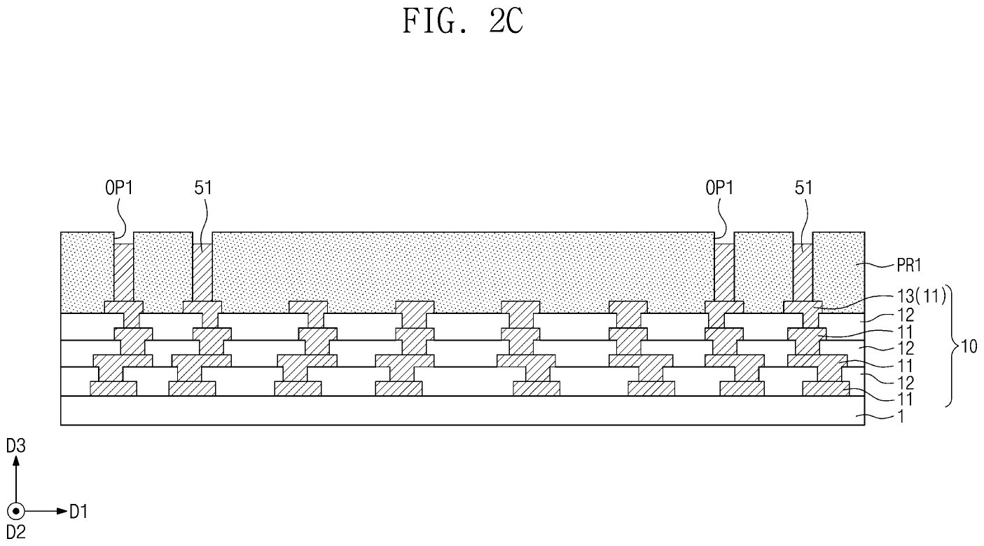

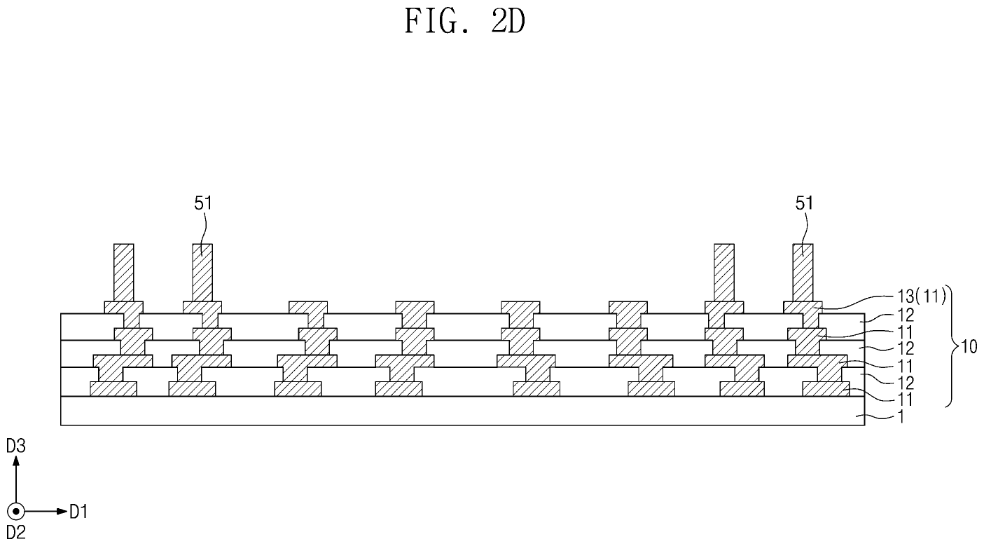

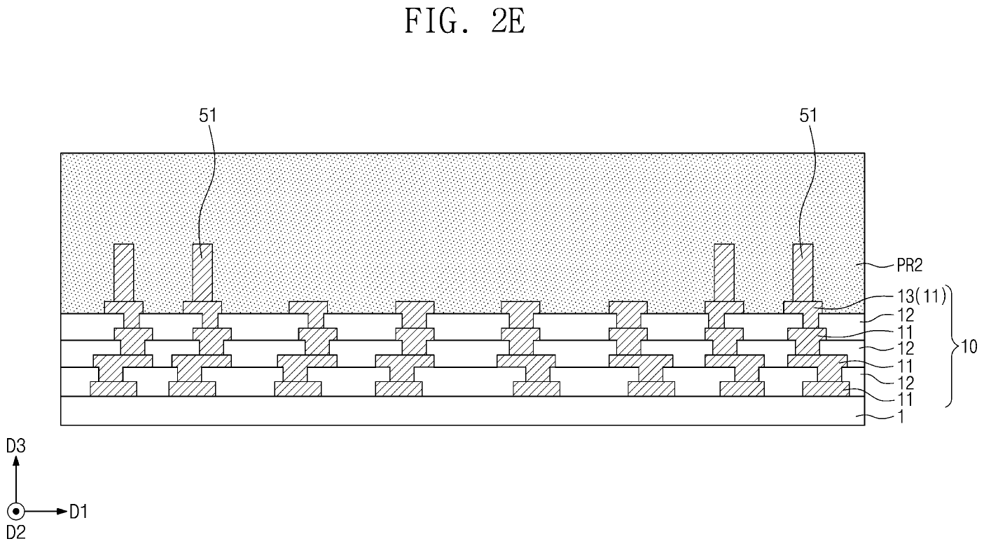

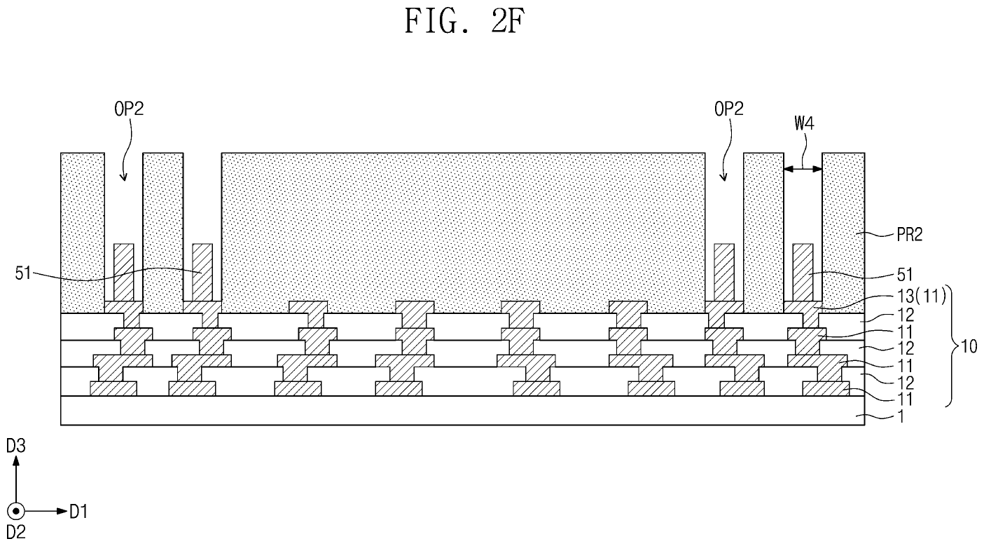

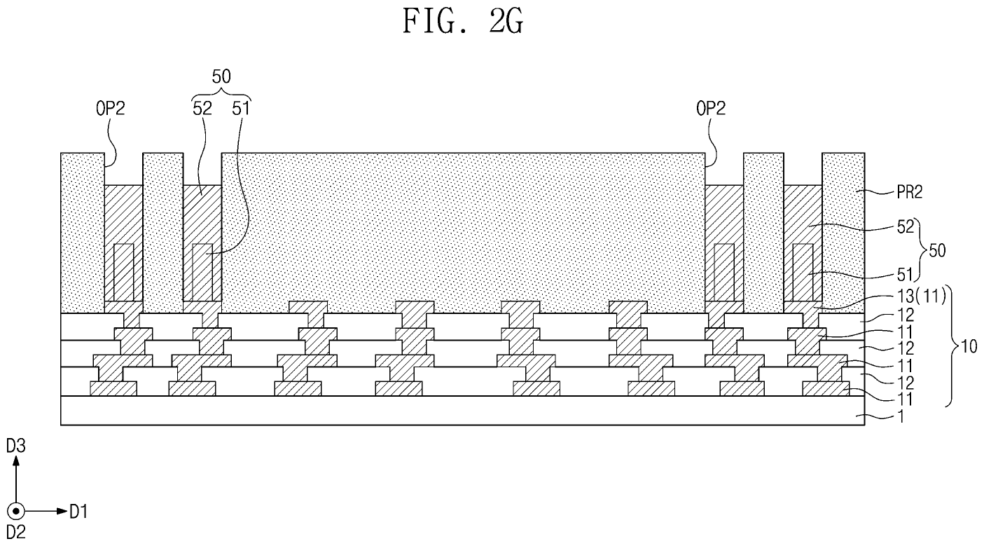

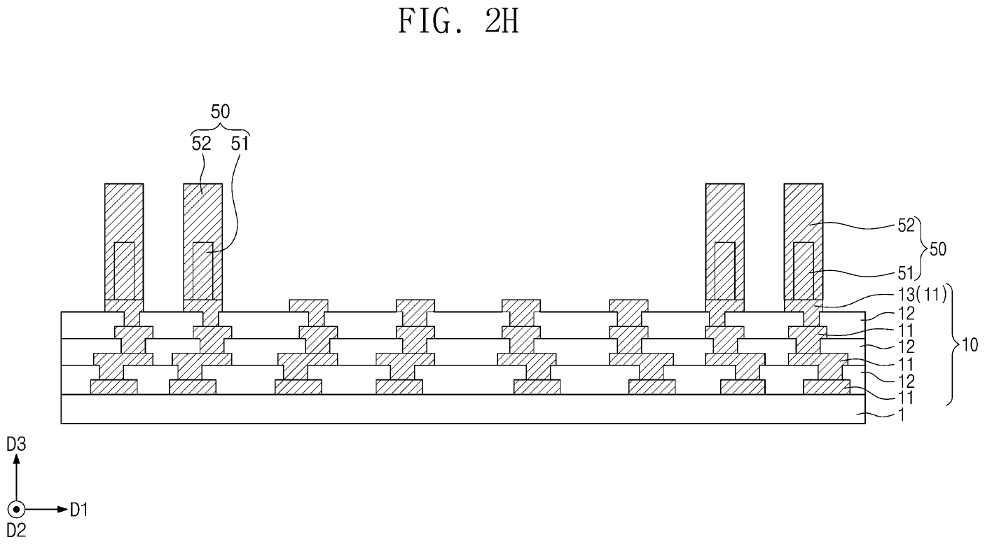

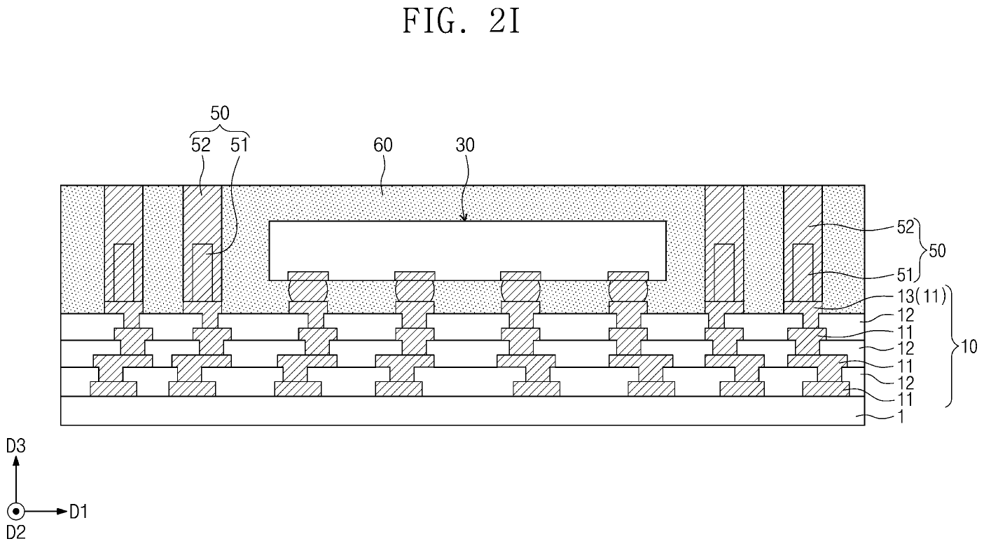

FIGS. 2A, 2B, 2C, 2D, 2E, 2F, 2G, 2H, and 2I illustrate cross-sectional views showing a method of fabricating a semiconductor package according to FIGS. 1A, 1B, and 1C.

Referring to FIG. 2A, a first structure 10 may be formed on a support substrate 1. The formation of the first structure 10 may include forming a first dielectric layer 12 and forming a first conductive pattern 11. For example, a plurality of first dielectric layers 12 and a plurality of first conductive patterns 11 may be alternately formed on the support substrate 1, e.g., by respective photolithography processes. A first photoresist layer PR1 may be formed on the first structure 10. The first photoresist layer PR1 may cover uppermost conductive patterns 13 of the first structure 10.

Referring to FIG. 2B, first openings OP1 may be formed in the first photoresist layer PR1. In some embodiments, an exposure process may be performed on the first photoresist layer PR1, and an exposed portion of the first photoresist layer PR1 may be removed to form the first opening OP1. In some embodiments, an exposure process may be performed on the first photoresist layer PR1, and a non-exposed portion of the first photoresist layer PR1 may be removed to form the first opening OP1.

The first opening OP1 may expose a top surface of the uppermost conductive pattern 13 of the first structure 10. A width W3 in the first direction D1 of the first opening OP1 may be less than a width in the first direction D1 of a top surface of the uppermost conductive pattern 13 included in the first structure 10.

Referring to FIG. 2C, inner pillars 51 may be formed. The inner pillar 51 may be formed by an electroplating process in which the uppermost conductive pattern 13 of the first structure 10 is used as a seed. The inner pillar 51 may be formed in the first opening OP1. The inner pillar 51 may be formed to have a top surface located at a lower level than a top surface of the first photoresist layer PR1.

Referring to FIG. 2D, the first photoresist layer PR1 may be removed. The first photoresist layer PR1 may be removed to expose sidewalls of the inner pillars 51.

Referring to FIG. 2E, a second photoresist layer PR2 may be formed on the first structure 10. The second photoresist layer PR2 may cover the inner pillars 51 and the uppermost conductive patterns 13 of the first structure 10.

Referring to FIG. 2F, second openings OP2 may be formed in the second photoresist layer PR2. In some embodiments, an exposure process may be performed on the second photoresist layer PR2, and an exposed portion of the second photoresist layer PR2 may be removed to form the second opening OP2. In some embodiments, an exposure process may be performed on the second photoresist layer PR2, and a non-exposed portion of the second photoresist layer PR2 may be removed to form the second opening OP2.

The second opening OP2 may expose the top surface and the sidewall of the inner pillar 51. The second opening OP2 may expose the top surface of the uppermost conductive pattern 13 of the first structure 10. The width W3 in the first direction D1 of the first opening OP1 in the first photoresist layer PR1 may be less than a width W4 in the first direction D1 of the second opening OP2 in the second photoresist layer PR2. In some embodiments, the width W4 in the first direction D1 of the second opening OP2 may be the same as a width in the first direction D1 of the uppermost conductive pattern 13 of the first structure 10. In some embodiments, the width W4 in the first direction D1 of the second opening OP2 may be less than the width in the first direction D1 of the uppermost conductive pattern 13 of the first structure 10.

Referring to FIG. 2G, outer pillars 52 may be formed. The outer pillars 52 may be formed by an electroplating process in which the inner pillar 51 and the uppermost conductive pattern 13 of the first structure 10 are used as a seed. Each outer pillar 52 may be formed in a corresponding second opening OP2. Each outer pillar 52 may be formed to have a top surface at a lower level than a top surface of the second photoresist layer PR2. The outer pillar 52 may cover the sidewall and the top surface of the inner pillar 51. The outer pillar 52 may be formed to constitute a pillar structure 50 including the outer pillar 52 and the inner pillar 51.

In some embodiments, an electroplating process for forming the outer pillar 52 may be performed at a higher temperature than an electroplating process for forming the inner pillar 51. For example, the outer pillar 52 may be electroplated at about 55° C., and the inner pillar 51 may be electroplated at about 40° C. Therefore, grains of the outer pillar 52 may have an average size greater than that of grains of the inner pillar 51. In some embodiments, a current density of an electroplating process for forming the outer pillar 52 may be greater than that of an electroplating process for forming the inner pillar 51. Therefore, grains of the outer pillar 52 may have an average size greater than that of grains of the inner pillar 51.

Referring to FIG. 2H, the second photoresist layer PR2 may be removed. The second photoresist layer PR2 may be removed to expose sidewalls of the outer pillars 52.

Referring to FIG. 2I, a first semiconductor chip 30 may be electrically connected to the first structure 10. The electrical connection between the first structure 10 and the first semiconductor chip 30 may include forming first bumps 81 on the first semiconductor chip 30 and mounting the first bumps 81 and the first semiconductor chip 30 on the first structure 10. In some embodiments, a thermal compression process may be employed/performed to mount the first bumps 81 and the first semiconductor chip 30 on the first structure 10.

A first molding layer 60 may be formed to surround the first semiconductor chip 30 and the pillar structures 50. The first molding layer 60 may surround the outer pillar 52 of the pillar structure 50. In some embodiments, after the formation of the first molding layer 60 that covers the pillar structures 50, a chemical mechanical polishing (CMP) process may be employed/performed to remove an upper portion of the first molding layer 60 to expose the pillar structures 50.

Referring to FIG. 1B, a second structure 20 may be formed on the first molding layer 60 and the pillar structures 50. A second semiconductor chip 40 may be electrically connected to the second structure 20. The electrical connection between the second structure 20 and the second semiconductor chip 40 may include forming second bumps 82 on the second semiconductor chip 40 and mounting the second bumps 82 and the second semiconductor chip 40 on the second structure 20. In some embodiments, a thermal compression process may be employed/performed to mount the second bumps 82 and the second semiconductor chip 40 on the second structure 20.

A second molding layer 70 may be formed to surround the second semiconductor chip 40. The support substrate 1 may be removed from the bottom surface of the first structure 10, and third bumps 83 may be formed on the bottom surface of the first structure 10.

In a method of fabricating a semiconductor package according to some embodiments, the inner pillar 51 and the outer pillar 52 may be formed by individual processes to reduce a time required for forming the pillar structure 50.

In a method of fabricating a semiconductor package according to some embodiments, the inner pillar 51 may be used as a seed to perform an electroplating process to form the outer pillar 52, and thus even when a residue of the second photoresist layer PR2 is present in the second opening OP2, the outer pillar 52 may be formed to have a desired size and shape.

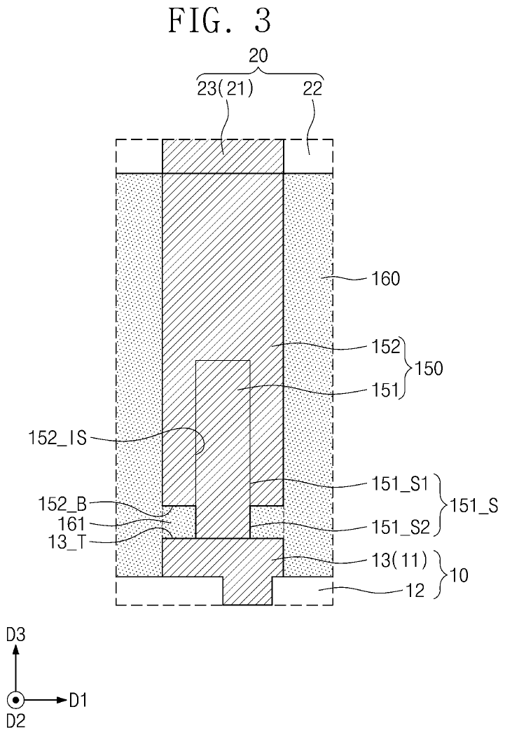

FIG. 3 illustrates an enlarged cross-sectional view showing a semiconductor package according to some embodiments.

Referring to FIG. 3, a pillar structure 150 of a semiconductor package may include an inner pillar 151 and an outer pillar 152. The inner pillar 151 may be provided on the uppermost conductive pattern 13 of the first structure 10. The outer pillar 152 may be provided on the inner pillar 151. The outer pillar 152 may be spaced apart in the third direction D3 from the uppermost conductive pattern 13 of the first structure 10. For example, a bottom surface 152_B of the outer pillar 152 may be spaced apart in the third direction D3 from the top surface 13_T of the uppermost conductive pattern 13 of the first structure 10.

A first molding layer 160 may include an intervening part 161 interposed between the outer pillar 152 and the uppermost conductive pattern 13 of the first structure 10. The intervening part 161 may be interposed between the bottom surface 152_B of the outer pillar 152 and the top surface 13_T of the uppermost conductive pattern 13 of the first structure 10. The intervening part 161 may be in contact with the bottom surface 152_B of the outer pillar 152, the top surface 13_T of the uppermost conductive pattern 13 of the first structure 10, and a sidewall 151_S of the inner pillar 151.

The sidewall 151_S of the inner pillar 151 may include a first part 151_S1 in contact with an inner sidewall 152_IS of the outer pillar 152 and a second part 151_S2 in contact with the intervening part 161 of the first molding layer 160.

A top surface of the intervening part 161 may be in contact with the bottom surface 152_B of the outer pillar 152. A sidewall of the intervening part 161 may be in contact with the second part 151_S2 of the sidewall 151_S of the inner pillar 151. A bottom surface of the intervening part 161 may be in contact with the top surface 13_T of the uppermost conductive pattern 13 of the first structure 10.

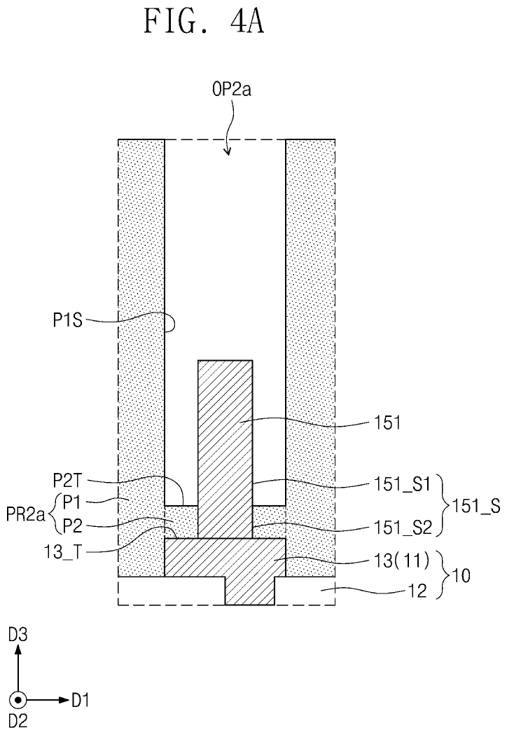

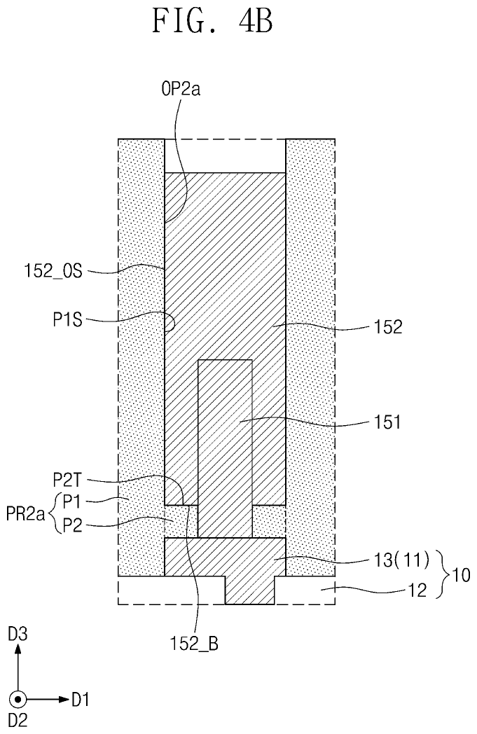

FIGS. 4A and 4B illustrate enlarged cross-sectional views showing a method of fabricating a semiconductor package according to FIG. 3.

Referring to FIG. 4A, a first photoresist layer including a first opening may be formed on the first structure 10. An inner pillar 151 may be formed in the first opening. The first photoresist layer may be removed after forming the inner pillar 151, and a second photoresist layer PR2a may be formed on the first structure 10 and on the inner pillar 151. A second opening OP2a may be formed in the second photoresist layer PR2a.

The second photoresist layer PR2a may include a first part P1 that defines a sidewall of the second opening OP2a and a second part P2 that defines a bottom surface of the second opening OP2a. The first part P1 of the second photoresist layer PR2a may have a sidewall PIS that is/defines the sidewall of the second opening OP2a. The second part P2 of the second photoresist layer PR2a may have a top surface P2T that is/defines the bottom surface of the second opening OP2a.

The second part P2 of the second photoresist layer PR2a may be in contact with a second part 151_S2 of a sidewall 151_S of the inner pillar 151. The second part P2 of the second photoresist layer PR2a may be in contact with the top surface 13_T of the uppermost conductive pattern 13 of the first structure 10. The second part P2 of the second photoresist layer PR2a may overlap in the third direction D3 with the second opening OP2a and the uppermost conductive pattern 13 of the first structure 10.

Referring to FIG. 4B, an outer pillar 152 may be formed in the second opening OP2a. The outer pillar 152 may be formed by an electroplating process in which the inner pillar 151 is used as a seed. A bottom surface 152_B of the outer pillar 152 may be in contact with the top surface P2T of the second part P2 of the second photoresist layer PR2a. An outer sidewall 152_OS of the outer pillar 152 may be in contact with the sidewall PIS of the first part P1 of the second photoresist layer PR2a. As the second photoresist layer PR2a includes the second part P2, the outer pillar 152 may be formed to be spaced apart from the uppermost conductive pattern 13 of the first structure 10. For example, the bottom surface 152_B of the outer pillar 152 may be spaced apart from the top surface 13_T of the uppermost conductive pattern 13 of the first structure 10 in the third direction D3 (e.g., in the vertical direction).

Referring to FIG. 3, the second photoresist layer PR2a may be removed after forming outer pillar 152 in the second opening OP2a. A first molding layer 160 may be formed, e.g., after the first semiconductor chip 30 with the first bumps 81 attached on its bottom surface is mounted on the first structure 10. The second part P2 of the second photoresist layer PR2a may be removed to form an empty space, e.g., at the same process removing the second photoresist layer PR2a, and an intervening part 161 of the first molding layer 160 may be formed in the empty space, e.g.,, at the same process forming the other part of the first molding layer 160.

In a method of fabricating a semiconductor package according to some embodiments, even when the second part P2 of the second photoresist layer PR2a is formed (e.g., remains) on the top surface 13_T of the uppermost conductive 13 in a process for forming the second opening OP2a, the inner pillar 151 may be used as a seed to perform an electroplating process to form the outer pillar 152 having a desired size and shape.

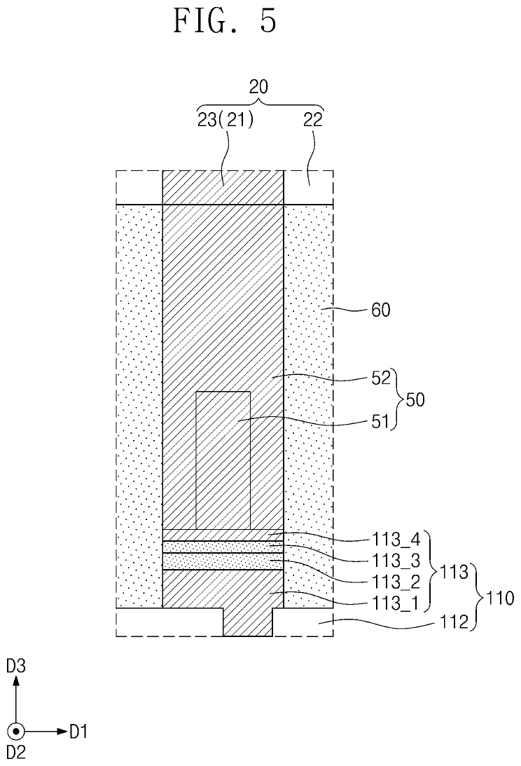

FIG. 5 illustrates an enlarged cross-sectional view showing a semiconductor package according to some embodiments.

Referring to FIG. 5, a first structure 110 of a semiconductor package may include a dielectric layer 112 and an uppermost conductive pattern 113 on the dielectric layer 112. The uppermost conductive pattern 113 of the first structure 110 may include a conductive layer 113_1 on the dielectric layer 112, a first metal layer 113_2 on the conductive layer 113_1, a second metal layer 113_3 on the first metal layer 113_2, and a seed layer 113_4 on the second metal layer 113_3.

The first metal layer 113_2, the second metal layer 113_3, and the seed layer 113_4 may include or be formed of conductive materials different from each other. For example, the first metal layer 113_2 may include or be formed of nickel, the second metal layer 113_3 may include or be formed of gold, and the seed layer 113_4 may include or be formed of copper. The seed layer 113_4 may include or be formed of a conductive material the same as that of the inner pillar 51 and the outer pillar 52 of the pillar structure 50. The inner pillar 51 and the outer pillar 52 may be provided on (e.g., contact) the seed layer 113_4.

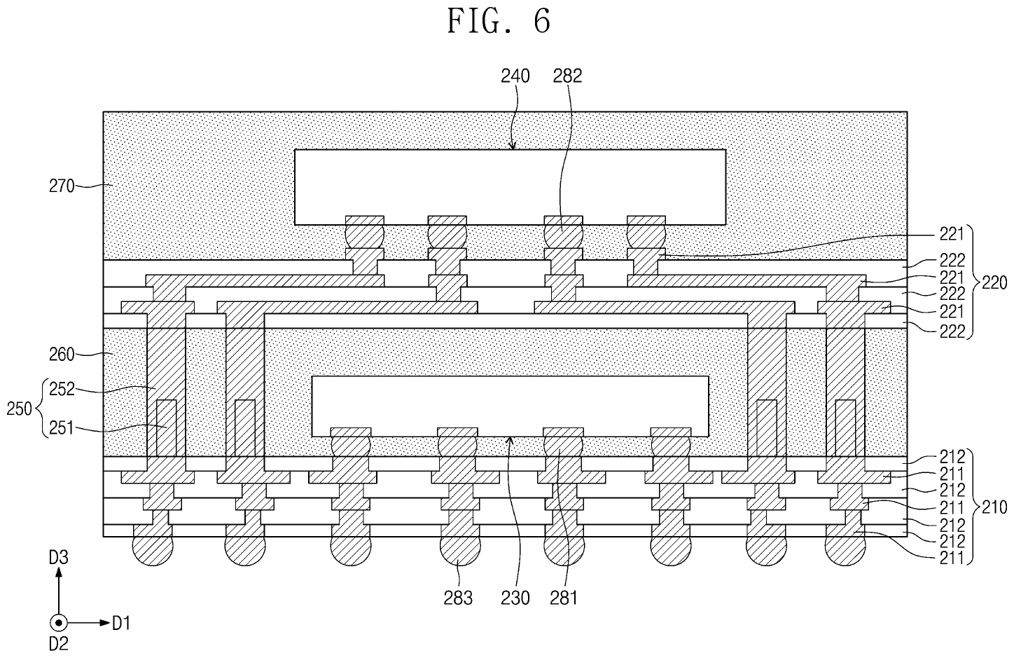

FIG. 6 illustrates a cross-sectional view showing a semiconductor package according to some embodiments.

Referring to FIG. 6, a semiconductor package may include a first structure 210, pillar structures 250 on the first structure 210, a first semiconductor chip 230 mounted on the first structure 210, a first molding layer 260 on the first structure 210, a second structure 220 on the first molding layer 260, a second semiconductor chip 240 mounted on the second structure 220, a second molding layer 270 on the second structure 220, first bumps 281 that electrically connect the first semiconductor chip 230 to the first structure 210, second bumps 282 that electrically connect the second semiconductor chip 240 to the second structure 220, and third bumps 283 connected to (e.g., contacting) a lower portion/surface of the first structure 210.

Each pillar structure 250 may include an inner pillar 251 and an outer pillar 252 that surrounds the inner pillar 251. The first structure 210 may include first conductive patterns 211 and first dielectric layers 212. The first conductive patterns 211 may include a via part (e.g., extending in a vertical direction) for vertical connection and a line part (e.g., extending in a horizontal direction) for horizontal connection. The via part of the first conductive pattern 211 may be located at a higher level than the line part of the first conductive pattern 211. For example, some via parts and some line parts of the first conductive patterns 211 may be integrally formed in the same pattern forming process, and a via part of an integrally formed first conductive pattern 211 may be located at a higher level than a line part of the integrally formed first conductive pattern 211. The second structure 220 may include second conductive patterns 221 and second dielectric layers 222. The second conductive patterns 221 may include a via part (e.g., extending in a vertical direction) for vertical connection and a line part (e.g., extending in a horizontal direction) for horizontal connection. The via part of the second conductive pattern 221 may be located at a lower level than the line part of the second conductive pattern 221. For example, some via parts and some line parts of the second conductive patterns 221 may be integrally formed in the same pattern forming process, and a via part of an integrally formed second conductive pattern 221 may be located at a lower level than a line part of the integrally formed second conductive pattern 221.

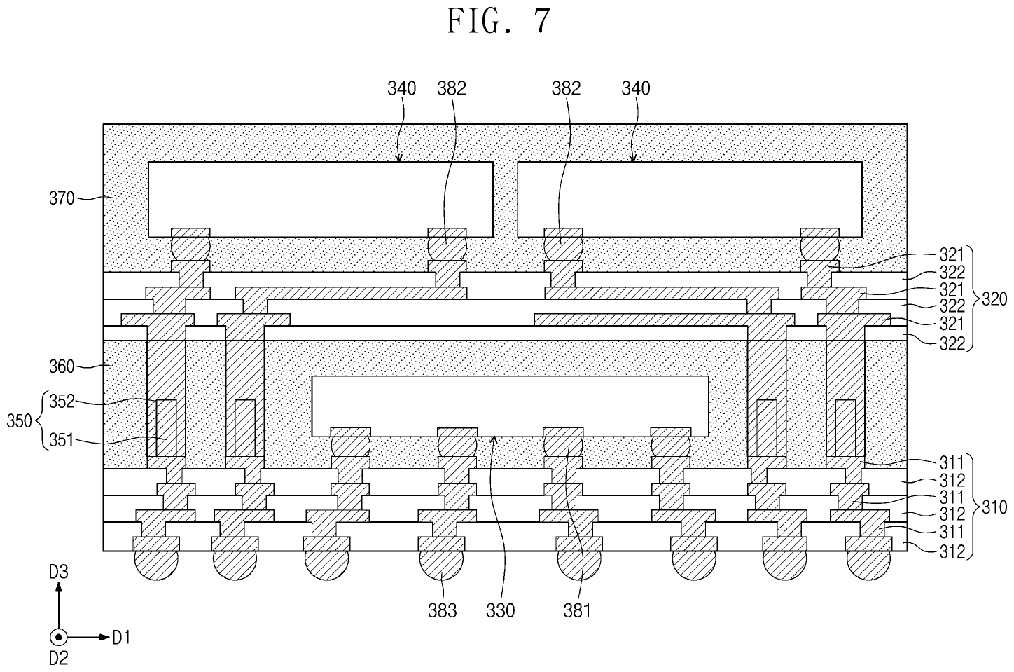

FIG. 7 illustrates a cross-sectional view showing a semiconductor package according to some embodiments.

Referring to FIG. 7, a semiconductor package may include a first structure 310, pillar structures 350 on the first structure 310, a first semiconductor chip 330 mounted on the first structure 310, a first molding layer 360 on the first structure 310, a second structure 320 on the first molding layer 360, a plurality of second semiconductor chips 340 mounted on the second structure 320, a second molding layer 370 on the second structure 320, first bumps 381 that electrically connect the first semiconductor chip 330 to the first structure 310, second bumps 382 that electrically connect the second semiconductor chip 340 to the second structure 320, and third bumps 383 connected to (e.g. contacting) a lower portion (e.g., a lower surface) of the first structure 310. The second molding layer 370 may surround the plurality of second semiconductor chips 340.

The first structure 310 may include first conductive patterns 311 and first dielectric layers 312. The second structure 320 may include second conductive patterns 321 and second dielectric layers 322. Each pillar structure 350 may include an inner pillar 351 and an outer pillar 352.

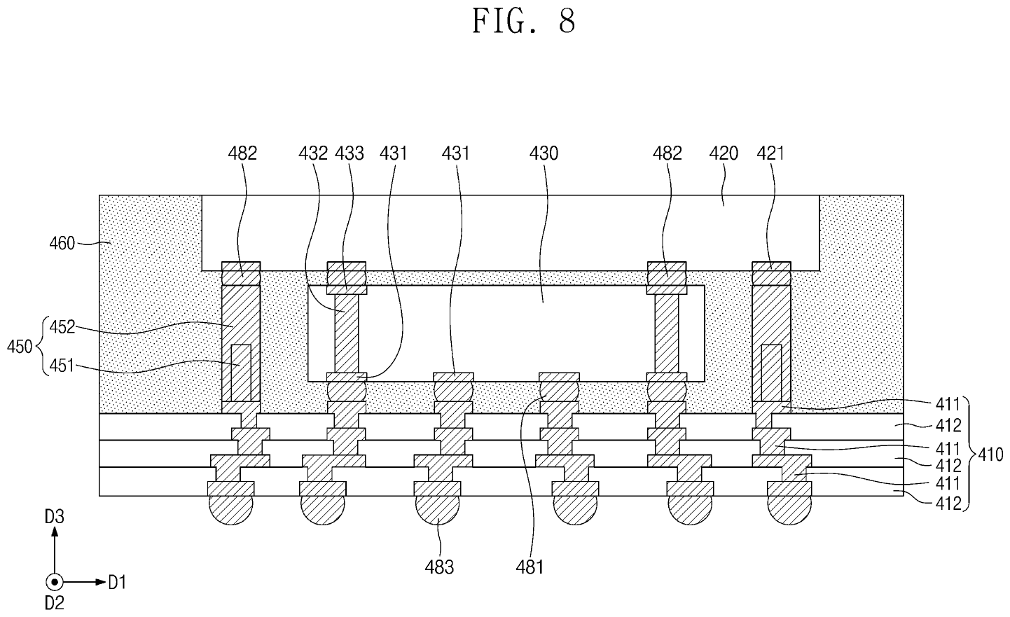

FIG. 8 illustrates a cross-sectional view showing a semiconductor package according to some embodiments.

Referring to FIG. 8, a semiconductor package may include a first structure 410, pillar structures 450 on the first structure 410, a semiconductor chip 430 mounted on the first structure 410, a molding layer 460 on the first structure 410, a second structure 420 on the molding layer 460, first bumps 481 that electrically connect the semiconductor chip 430 to the first structure 410, second bumps 482 that electrically connect the second structure 420 to the pillar structures 450, and third bumps 483 connected to (contacting) a lower portion/surface of the first structure 410.

The first structure 410 may be a redistribution substrate including conductive patterns 411 and dielectric layers 412. The second structure 420 may be a semiconductor chip including pads 421. Each pillar structure 450 may include an inner pillar 451 and an outer pillar 452. The molding layer 460 may surround the second structure 420, the semiconductor chip 430, and the pillar structures 450. The molding layer 460 may cover (e.g., contact) a sidewall of the second structure 420. The semiconductor chip 430 may include a lower pad 431, a through via 432, and an upper pad 433. The through via 432 may electrically connect the lower pad 431 to the upper pad 433. The through via 432 may be a through silicon via that penetrates a semiconductor substrate of the semiconductor chip 430, e.g., in a vertical direction. The second structure 420 may have a width, e.g., in a horizontal direction, less than that of the first structure 410.

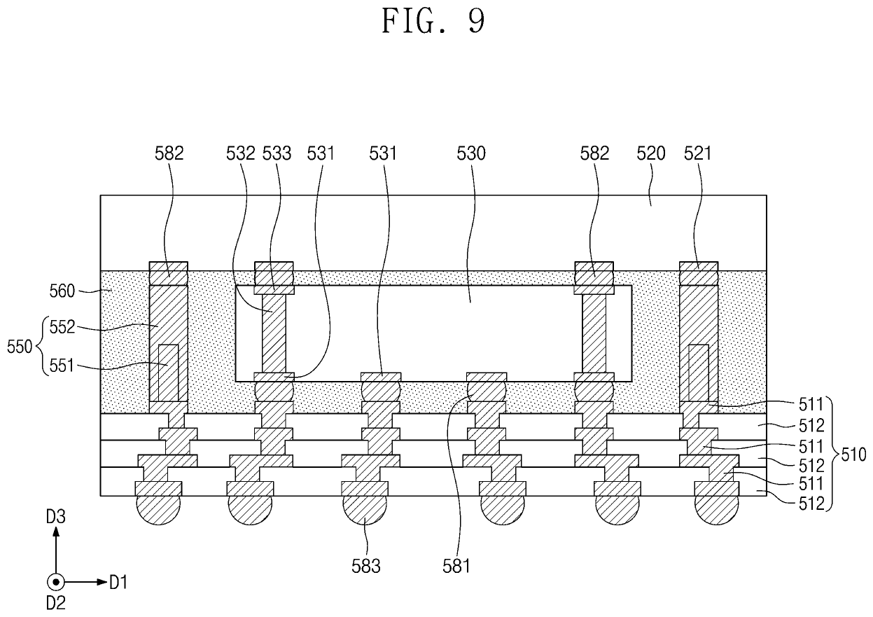

FIG. 9 illustrates a cross-sectional view showing a semiconductor package according to some embodiments.

Referring to FIG. 9, a semiconductor package may include a first structure 510, pillar structures 550 on the first structure 510, a semiconductor chip 530 mounted on the first structure 510, a molding layer 560 on the first structure 510, a second structure 520 on the molding layer 560, first bumps 581 that electrically connect the semiconductor chip 530 to the first structure 510, second bumps 582 that electrically connect the second structure 520 to the pillar structures 550, and third bumps 583 connected to (e.g., contacting) a lower portion of the first structure 510.

The first structure 510 may be a redistribution substrate including conductive patterns 511 and dielectric layers 512. The second structure 520 may be a semiconductor chip including pads 521. Each pillar structure 550 may include an inner pillar 551 and an outer pillar 552. The molding layer 560 may surround the semiconductor chip 530 and the pillar structures 550. The molding layer 560 may be disposed between the first structure 510 and the second structure 520. The molding layer 560 may cover/contact a bottom surface of the second structure 520. The semiconductor chip 530 may include a lower pad 531, a through via 532, and an upper pad 533. The second structure 520 may have a width in a horizontal direction (e.g., the first direction D1 and/or the second direction D2) the same as that of the first structure 510.

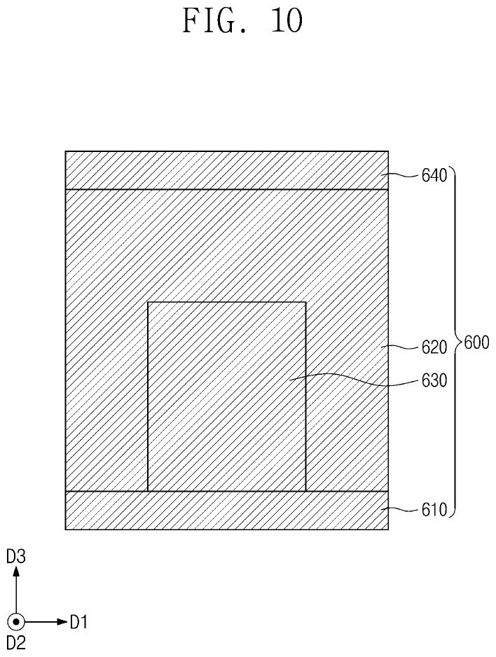

FIG. 10 illustrates a cross-sectional view showing a conductive structure according to some embodiments.

Referring to FIG. 10, a conductive structure 600 may include a seed layer 610, an inner conductive layer 630, an outer conductive layer 620 that surrounds the inner conductive layer 630, and a cover conductive layer 640 on the outer conductive layer 620.

The inner conductive layer 630 may be formed by an electroplating process in which the seed layer 610 is used as a seed. The outer conductive layer 620 may be formed by an electroplating process in which the inner conductive layer 630 is used as a seed. The seed layer 610, the inner conductive layer 630, and the outer conductive layer 620 may include or be formed of the same metallic material. For example, the seed layer 610, the inner conductive layer 630, and the outer conductive layer 620 may include or be formed of nickel or copper. The cover conductive layer 640 may include or be formed of a metallic material different from that of the seed layer 610, the inner conductive layer 630, and the outer conductive layer 620. For example, the cover conductive layer 640 may include or be formed of gold.

Bumps discussed in this description may have the same structure as or a similar structure to the conductive structure 600. For example, each of the first, second, and third bumps 81, 82, and 83 of FIG. 1B may have the same structure as or a similar structure to the conductive structure 600.

In a semiconductor package according to some embodiments of the present inventive concepts, a pillar structure may include an inner pillar and an outer pillar, and thus the pillar structure may have a uniform horizontal width and a uniform vertical width. The pillar structures of some embodiments of the present disclosure may also have a flat and smooth top surface, which is good for a contact reliability of the pillar structures with an upper structure.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context indicates otherwise.

Although the present invention has been described in connection with the some example embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

1. A semiconductor package, comprising:
a first structure that includes a conductive pattern;
a second structure spaced apart from the first structure;
a pillar structure between the first structure and the second structure, the pillar structure electrically connecting the first structure to the second structure; and
a semiconductor chip between the first structure and the second structure,
wherein the pillar structure includes an inner pillar on the conductive pattern and an outer pillar that surrounds the inner pillar,
wherein the outer pillar is in contact with a sidewall and a top surface of the inner pillar.

2. The semiconductor package of claim 1, wherein
the top surface of the inner pillar is parallel to a first direction, and
the sidewall of the inner pillar is parallel to a second direction that intersects the first direction.

3. The semiconductor package of claim 2, wherein a width in the first direction of the top surface of the inner pillar is less than a length in the second direction of the sidewall of the inner pillar.

4. The semiconductor package of claim 1, wherein the outer pillar is in contact with the conductive pattern.

5. The semiconductor package of claim 1, wherein the outer pillar and the inner pillar include the same conductive material.

6. The semiconductor package of claim 1, wherein an average size of grains of the inner pillar is less than an average size of grains of the outer pillar.

7. The semiconductor package of claim 1, wherein a density of grain boundaries in the inner pillar and a density of grain boundaries in the outer pillar are less than a density of grain boundaries at an interface between the inner pillar and the outer pillar.

8. The semiconductor package of claim 1, wherein the outer pillar is spaced apart from the conductive pattern.

9. The semiconductor package of claim 8, further comprising a molding layer that surrounds the pillar structure,
wherein the molding layer includes an intervening part between the outer pillar and the conductive pattern.

10. A semiconductor package, comprising:
a first structure that includes a conductive pattern;
a second structure spaced apart in a first direction from the first structure;
a pillar structure between the first structure and the second structure, the pillar structure electrically connecting the first structure to the second structure; and
a semiconductor chip between the first structure and the second structure, the semiconductor chip being spaced apart from the pillar structure in a second direction that intersects the first direction,
wherein the pillar structure includes an inner pillar on the conductive pattern and an outer pillar that surrounds the inner pillar,
wherein a width in the second direction of the inner pillar is less than a length in the first direction of the inner pillar.

11. The semiconductor package of claim 10, wherein a width in the second direction of a top surface of the inner pillar is less than a length in the first direction of a sidewall of the inner pillar.

12. The semiconductor package of claim 10, wherein the outer pillar includes:
an upper portion at a level higher than a level of a top surface of the inner pillar; and
a lower portion at a level lower than the level of the top surface of the inner pillar.

13. The semiconductor package of claim 12, wherein
the lower portion of the outer pillar has a cylindrical shape that surrounds the inner pillar, and
the upper portion of the outer pillar has a pillar shape.

14. The semiconductor package of claim 12, wherein a bottom surface of the lower portion of the outer pillar is in contact with a top surface of the conductive pattern.

15. The semiconductor package of claim 12, wherein a bottom surface of the lower portion of the outer pillar is spaced apart from a top surface of the conductive pattern.

16. The semiconductor package of claim 15, further comprising a molding layer that surrounds the semiconductor chip and the pillar structure,
wherein the molding layer includes an intervening part between the bottom surface of the lower portion of the outer pillar and the top surface of the conductive pattern.

17. The semiconductor package of claim 16, wherein a sidewall of the intervening part is in contact with a sidewall of the inner pillar.

18. The semiconductor package of claim 10, wherein
the conductive pattern includes a conductive layer, a metal layer on the conductive layer, and a seed layer on the metal layer,
the seed layer includes a conductive material the same as a conductive material of the inner pillar and the outer pillar, and
the metal layer includes a conductive material different from the conductive material of the seed layer, the inner pillar, and the outer pillar.

19. A semiconductor package, comprising:
a first structure that includes a conductive pattern;
a second structure spaced apart in a first direction from the first structure;
a pillar structure between the first structure and the second structure, the pillar structure electrically connecting the first structure to the second structure;
a first semiconductor chip mounted on the first structure and spaced apart from the pillar structure in a second direction that intersects the first direction;
a second semiconductor chip mounted on the second structure; and
a molding layer between the first structure and the second structure, the molding layer surrounding the first semiconductor chip and the pillar structure,
wherein the pillar structure includes an inner pillar on the conductive pattern and an outer pillar that surrounds the inner pillar,
wherein the inner pillar includes a sidewall parallel to the first direction and a top surface parallel to the second direction, and
wherein the outer pillar is in contact with the sidewall of the inner pillar and the top surface of the inner pillar.

20. The semiconductor package of claim 19, wherein a width in the second direction of the inner pillar is equal to or less than about 0.5 times a width in the second direction of the outer pillar.

21-29. (canceled)
